(19) United States
(12) Patent Application Publication
(10) Pub. No.: US 2009/0160004 A1
(43) Pub. Date: Jun. 25, 2009

(54) SEMICONDUCTOR DEVICE AND METHOD FOR MANUFACTURING THE DEVICE

(76) Inventor: Kyung-Min Park, Namdong-gu (KR)

Correspondence Address: SHERR & VAUGHN, PLLC, 620 HERNDON PARKWAY, SUITE 200, HERNDON, VA, 20170, US

(21) Appl. No.: 12/334,507

(22) Filed: Dec. 14, 2008

(30) Foreign Application Priority Data
Dec. 21, 2007 (KR) 10-2007-0135129

(51) Int. Cl. H01L 21/04; H01L 31/0224; H01L 31/0232

(52) U.S. Cl. 257/432; 438/70; 257/E31.127; 257/E21.041; 257/E31.124

(57) ABSTRACT

Embodiments relate to a semiconductor device and a method for manufacturing a semiconductor device. According to embodiments, a method may include forming a metal layer on and/or over a lower structure formed on and/or over a semiconductor substrate, forming neighboring metal lines by patterning the metal layer by a photolithography process, forming an insulating layer on and/or over a surface of the lower structure and forming a void between the metal lines, and performing heat treatment to the metal lines and the insulating layer having the void. According to embodiments, a void may be used as a buffer against expansion of the metal lines in sintering due to a difference in a thermal expansion coefficient. This may prevent a blister phenomenon that may separate an insulating film from metal lines.

The present application claims priority under 35 U.S.C. 119 to Korean Patent Application No. 10-2007-0135129 (filed on Dec. 21, 2007), which is hereby incorporated by reference in its entirety.

### BACKGROUND

In a semiconductor device such as an image sensor, a sintering process may be performed after micro lenses (ML) may be formed. This may improve characteristics of a dark signal.

FIGS. 1A through 1E illustrate plan views of an image sensor that may be a semiconductor device. Referring to FIGS. 1A through 1E, micro lenses may be formed. An image sensor may then be sintered at a temperature of approximately 450° C. At this point, there may be a difference in stress between metal lines and an oxide film, which may be an insulating layer. This may be because metal lines and an oxide film may have different thermal expansion coefficients. A stress difference may cause blister phenomena 10, 12, 14, 16 and 18, in which an oxide film may separate from metal lines, as shown in FIGS. 1A through 1E. In an image sensor that may be sensitive to light, oxide particles may move to a photodiode region of a pixel or the like. This may cause a reduction in light efficiency.

FIG. 2 is a graph showing characteristics of a dark signal varying according to temperature and time in a sintering process. In FIG. 2, a horizontal axis may represent a wafer lot and a vertical axis may represent measurement values of a dark signal. Referring to FIG. 2, if a sintering temperature is raised from temperature 20 of approximately 400° C. to temperature 22 of approximately 450° C., characteristics of a dark signal may be improved by about 50, even for a short period of time. However, if a sintering temperature is raised, although dark signal characteristics may be improved, a blister phenomenon may become more severe. This may be because if a sintering temperature is raised, a larger difference in stress may occur between metal lines and an oxide film.

### SUMMARY

Embodiments relate to a semiconductor device, such as an image sensor or a flash memory, and to a semiconductor device and a method for manufacturing the same.

Embodiments relate to a semiconductor device and a method for manufacturing a semiconductor device that may prevent a blister phenomenon, in which metal and an insulating film may be separated from each other, due to heat treatment, such as sintering.

According to embodiments, a method for manufacturing a semiconductor device may include at least one of the following. Forming a metal layer on and/or over a lower structure formed on and/or over a semiconductor substrate. Forming neighboring metal lines by patterning the metal layer, for example using a photolithography process. Forming an insulating layer on and/or over a surface, for example an entire surface, of the lower structure having the metal lines while forming a void between the metal lines. Performing heat treatment to the metal lines and the insulating layer having the void.

According to embodiments, a semiconductor device, may include at least one of the following. Neighboring metal lines formed on and/or over a lower structure formed on and/or over a semiconductor substrate. An insulating layer formed between the metal lines and having a void between the neighboring metal lines. According to embodiments, the metal lines and the insulating layer having the void may undergo a heat treatment.

According to embodiments, in a semiconductor device and a method of manufacturing a semiconductor device, a void may be intentionally formed in the insulating layer between the metal lines. The void may be used as a buffer against expansion of metal lines in sintering that may be caused by a difference in a thermal expansion coefficient. According to embodiments, it may be possible to reduce and/or prevent a blister phenomenon in which the insulating film may be separated from the metal lines. According to embodiments, blisters may not be generated while characteristics of a dark signal may be improved by sintering. According to embodiments, light efficiency of a image sensor may be improved.

### DRAWINGS

FIGS. 1A through 1E illustrate plan views of an image sensor serving as a semiconductor device.

FIG. 2 is a graph showing characteristics of a dark signal varying according to temperature and time in a sintering process.

Example FIG. 3A illustrate a cross-sectional view of a semiconductor device according to embodiments.

FIG. 3B illustrates a cross-sectional view of a related art semiconductor device.

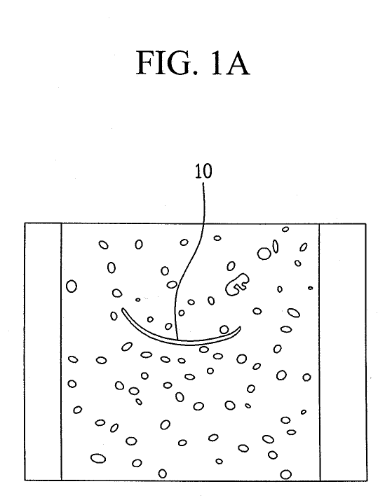

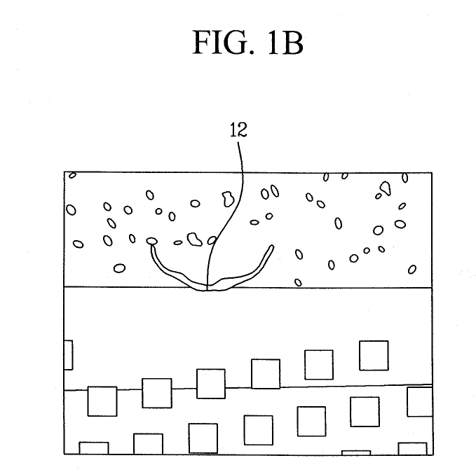

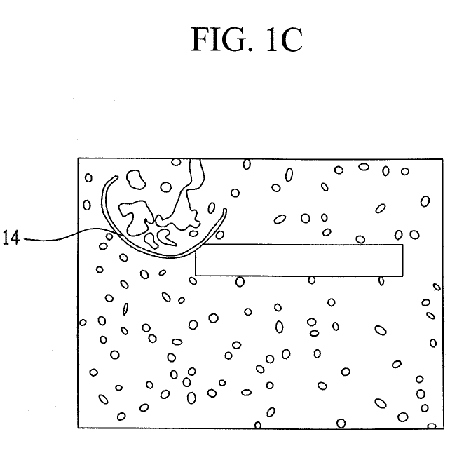

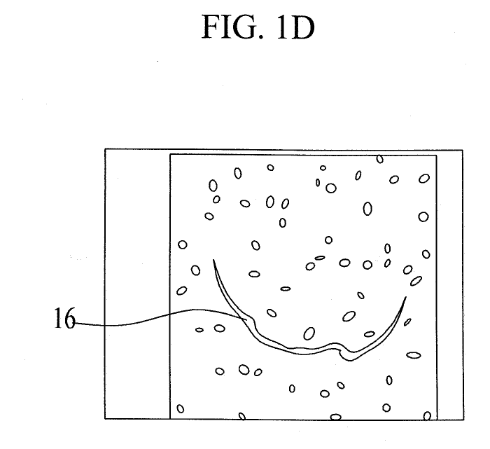

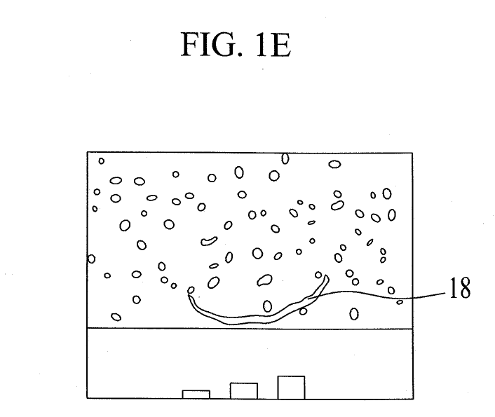

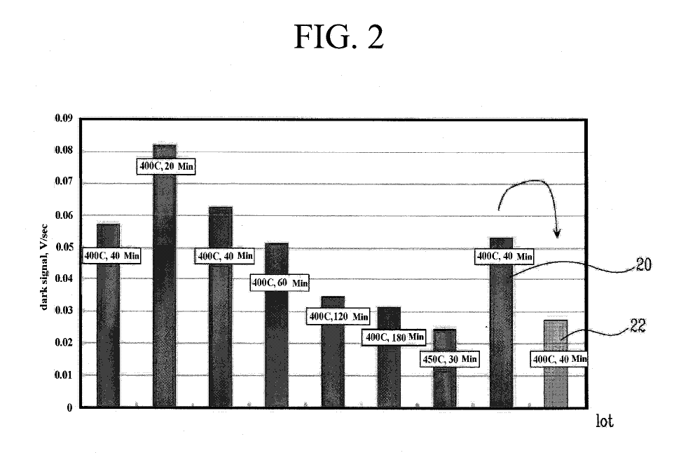

Example FIGS. 4A through 4E illustrate cross-sectional views showing a method of manufacturing a semiconductor device, according to embodiments.

Example FIG. 5 illustrates a semiconductor device, according to embodiments.

Example FIG. 6 illustrates a cross-sectional view of a general image sensor.

Example FIG. 7 is a diagram illustrating metal lines and insulating layers in an image sensor, which may be a semiconductor device, according to embodiments.

Example FIG. 8 illustrates a SEM view of a semiconductor device, according to embodiments.

### DESCRIPTION

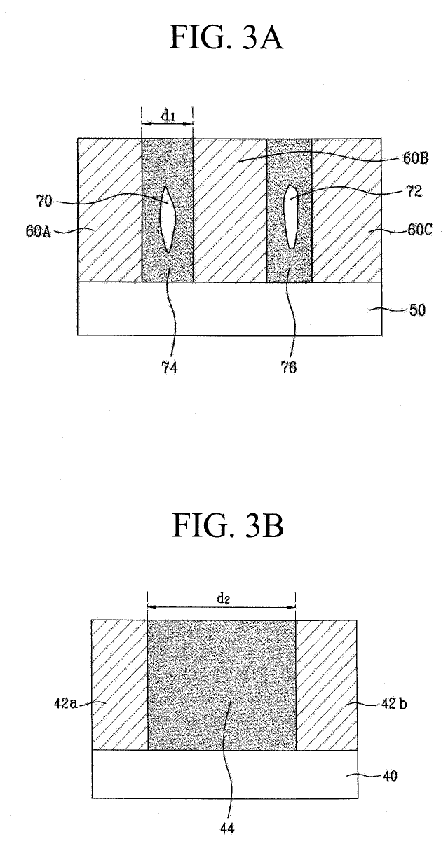

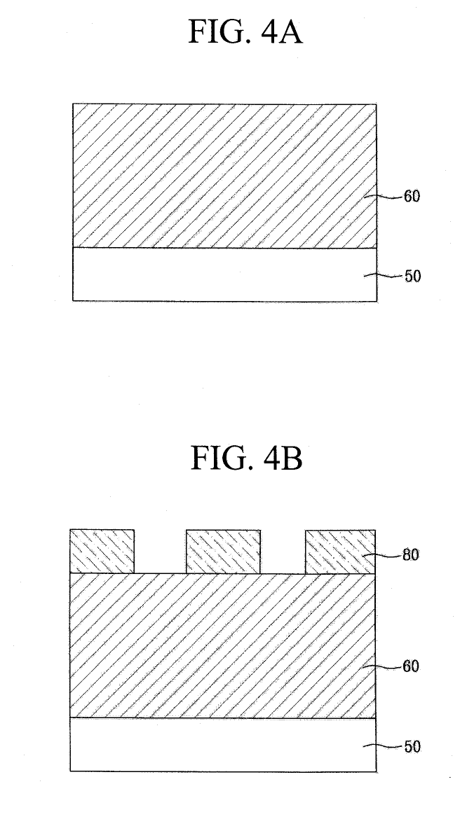

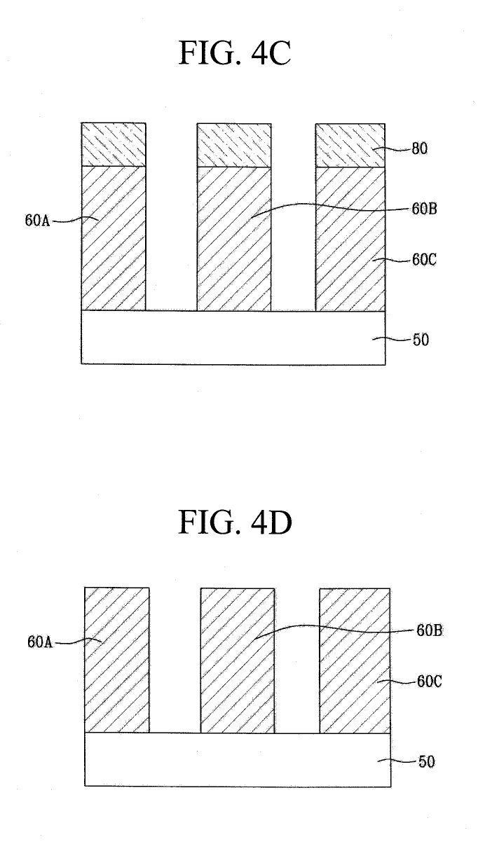

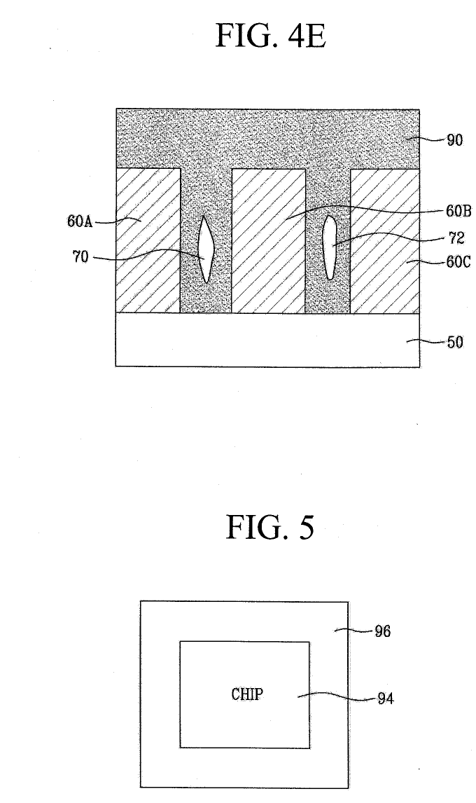

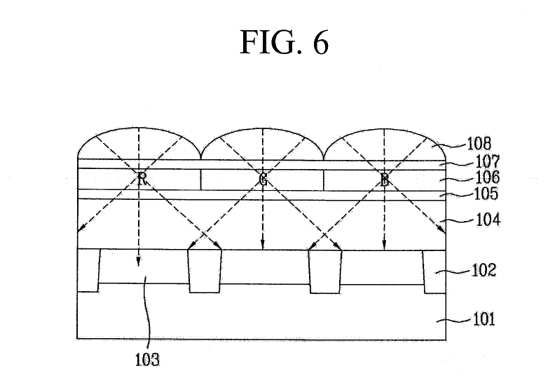

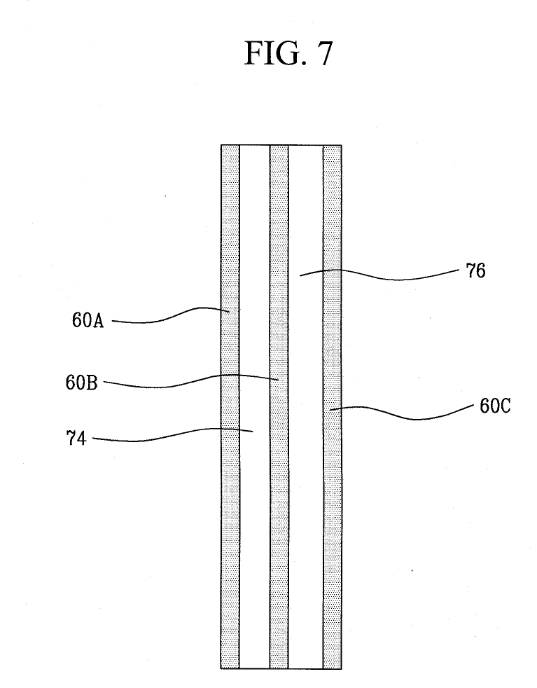

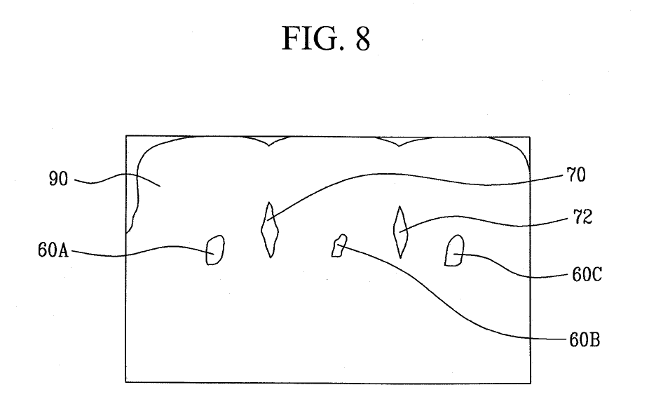

Example FIG. 3A and FIG. 3B illustrate a cross-sectional view of a semiconductor device according to embodiments and a cross-sectional view of a related art semiconductor device, respectively.

Referring to example FIG. 3A, metal lines 60A, 60B, and 60C according to embodiments may be formed adjacent to each other on and/or over a lower structure 50. Lower structure 50 may be formed on and/or over a semiconductor substrate. Insulating layer 74 may be formed between metal lines 60A and 60B and insulating layer 76 may be formed between metal lines 60B and 60C. According to embodiments, insulating layers 74 and 76 may be inter-metal dielectric (IMD) films.

According to embodiments, insulating layer 74, which may be formed between adjacent metal lines 60A and 60B may have void 70. According to embodiments, insulating layer 76, which may be formed between adjacent metal lines 60B and 60C, may have void 72. Heat treatment, such as sintering, may be performed to a chip. A chip may include a semiconductor substrate, metal lines 60A, 60B and 60C, and insulating layers 74 and 76.

In a related art semiconductor device shown in FIG. 3B, distance d2 of insulating layer 44 formed between metal lines 42a and 42b disposed on and/or over lower structure 40 may be relatively large. Hence, a void may not be formed when insulating layer 44 may be formed. Accordingly, in a sintering process, insulating layer 44 may separate from metal lines 42a and 42b due to a difference in a thermal expansion coefficient between metal lines 42a and 42b and insulating layer 44. This may generate blisters.

According to embodiments, as shown in example FIG. 3A, distance d1 of insulating layers 74 and 76, which may be formed between metal lines 60A, 60B, and 60C disposed on and/or over lower structure 50 may be smaller than distance d2. According to embodiments, voids 70 and 72 may not be formed when insulating layers 74 and 76 may be formed. Thus, in a sintering process, since there may be a difference in a thermal expansion coefficient between metal lines 60A, 60B, and 60C and insulating layers 74 and 76, although metal lines 60A, 60B, and 60C may expand, voids 70 and 72 may serve as a buffer against an expansion. According to embodiments, it may be possible to prevent insulating layers 74 and 76 from separating from metal lines 60A and 60C.

Although only three metal lines 60A, 60B and 60C are illustrated in example FIG. 3A in a semiconductor device according to embodiments, embodiments may not be limited thereto. According to embodiments, only two metal lines may exist. According to embodiments, four or more metal lines may exist. According to embodiments, a semiconductor device may intentionally have a void formed between metal lines for sintering.

Example FIGS. 4A through 4E illustrate cross-sectional views showing a method of manufacturing a semiconductor device according to embodiments. Referring to example FIG. 4A, metal layer 60 may be formed on and/or over lower structure 50. According to embodiments, lower structure 50 may be formed on and/or over a semiconductor substrate. According to embodiments, metal layer 60 may be formed of aluminum (Al).

Referring to example FIGS. 4B and 4C, metal layer 60 may be patterned by a photolithography process. This may form adjacent metal lines 60A, 60B, and 60C. According to embodiments, as shown in example FIG. 4B, etching mask layer 80 may be formed on and/or over metal layer 60. Etching mask may have open areas to form insulating layers 74 and 76. According to embodiments, a width of open areas of etching mask layer 80 may correspond to distance d1 between metal lines 60A and 60B or metal lines 60B and 60C.

According to embodiments, it may be possible to determine whether voids 70 and 72 have been formed between metal lines 60A, 60B, and 60C and a size of voids 70 and 72 may be controlled by adjusting width d1 of open areas of etching mask layer 80. According to embodiments, if a width of open areas of etching mask layer 80 decreases, a probability of formation of voids 70 and 72 may increase. According to embodiments, a width of open areas of etching mask layer 80 may be formed smaller than widths of metal lines 60A, 60B, and 60C.

According to embodiments, width d1 of open areas of etching mask layer 80 may be approximately 0.09 μm to 0.15 μm. According to embodiments, width d1 of open areas of etching mask layer 80 may be approximately 0.11 μm, and a width of unopened areas of etching mask layer 80, that is, a width of metal lines 60A, 60B, and 60C may be approximately 0.16 μm.

Referring to example FIG. 4C, metal layer 60 may be etched by an etching process. Etching mask layer 80 may be used for the etching. This may form metal lines 60A, 60B, and 60C. According to embodiments, if metal lines 60A, 60B, and 60C are formed, etching mask layer 80 may be removed, as shown in example FIG. 4D.

Referring to example FIG. 4E, insulating layer 90 may be formed on and/or over a surface, for example an entire surface, of lower structure 50 having metal lines 60A, 60B, and 60C. According to embodiments, insulating layer 90 may be formed of an oxide film. According to embodiments, insulating layer 90 may be filled between metal lines 60A, 60B, and 60C. According to embodiments, voids 70 and 72 may be formed between metal lines 60A, 60B, and 60C by setting a small distance between metal lines 60A, 60B, and 60C.

Referring to example FIG. 4E, insulating layer 90 may be polished by a chemical mechanical polishing (CMP) process. This may expose metal lines 60A, 60B, and 60C, and may complete metal lines 60A, 60B, and 60C. If a CMP process is performed, some upper surfaces of metal lines 60A, 60B, and 60C shown in FIG. 4E may be polished at the same time.

According to embodiments, voids 70 and 72 may be formed between metal lines 60A, 60B, and 60C. Hence, although metal lines 60A, 60B, and 60C may expand due to a subsequent heat treatment, for example, heat treatment for depositing metal, heat treatment for depositing an oxide film, sintering, or other heat treatment, voids between metal lines 60A, 60B, and 60C may serve as a buffer against expansion. According to embodiments, this may prevent a blister phenomenon.

Example FIG. 5 illustrates an example of a semiconductor device according to embodiments. According to embodiments, a semiconductor device may include chip (or die) 94 and guard line 96. Referring to example FIG. 5, chip 94 may be any one of semiconductor devices that may have various functions. For example, chip 94 may be a semiconductor device such as an image sensor chip or a flash memory chip.

According to embodiments, chip 94 may include lower structure 50 shown in example FIG. 3A. Guard line 96 may be formed by metal lines 60A, 60B, and 60C and insulating layers 74 and 76. Guard line 96 may protect chip 94 or distinguish chip 94 from other chips.

In a related art semiconductor device, a guard line of a chip may be formed by one metal line. Accordingly, an insulating film may be easily separated from a metal line due to a difference in a thermal expansion coefficient between metal lines and an insulating layer by a subsequent sintering.

According to embodiments, however, a plurality of metal lines 60A, 60B, and 60C and voids 70 and 72 may be provided instead of a single metal line. Accordingly, insulating layers 74 and 76 may be hardly separated from metal lines 60A, 60B, and 60C.

A semiconductor device according to embodiments will be described with reference to the accompanying drawings. According to embodiments, chip 94 shown in example FIG. 5 may be an image sensor chip. According to embodiments, chip 94 may be any other chip. For purposes of example, an image sensor chip will be described.

Example FIG. 6 illustrates a cross-sectional view of a general image sensor. Referring to example FIG. 6, photodiodes 103 may be formed on and/or over semiconductor substrate 101 and may be separated by device isolation films 102. Interlayer insulating film 104 may be formed on and/or over photodiodes 103. Protective film 105, color filter layers 106, and planarization layer 107 may be sequentially deposited and formed on and/or over interlayer insulating film 104. Micro lenses 108 may be formed on and/or over planarization layer 107.

According to embodiments, to manufacture an image sensor as illustrated in example FIG. 6, device isolation films 102 may be formed on and/or over semiconductor substrate 101. Photodiodes 103 may then be formed. Interlayer insulating film 104 may be formed on and/or over photodiodes 103. Protective film 105, color filter layers 106, and planarization layer 107 may then be deposited and formed on and/or over interlayer insulating film 104. According to embodiments, micro lenses 108 may be formed on and/or over planarization layer 107.

Example FIG. 7 is a diagram illustrating metal lines 60A, 60B, and 60C and insulating layers 74 and 76 of a guard line in an image sensor that may serve as a semiconductor device. Referring to example FIGS. 6 and 7, guard line 96 of chip 94 may be formed after forming micro lenses 108 of an image sensor embedded in chip 94. A metal layer may be disposed at an outer portion of an image sensor chip. Referring to example FIG. 7, which is an enlarged view of a portion of a metal layer of an image sensor chip, a metal layer may include three metal lines 60A, 60B, and 60C. Insulating layers 74 and 76 may be formed between metal lines 60A, 60B, and 60C.

Example FIG. 8 illustrates a SEM view of a semiconductor device, according to embodiments. From a cross-sectional view of an image sensor shown in example FIG. 7, as shown in example FIG. 8, it may be seen that voids 70 and 72 may be formed if insulating layer 90 is filled between metal lines 60A, 60B, and 60C, which may be used as guard line 96.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method, comprising:
forming a metal layer over a lower structure formed over a semiconductor substrate;
forming metal lines by patterning the metal layer using a photolithography process;
forming an insulating layer over a surface of the lower structure between the metal lines and forming a void between the metal lines; and
performing heat treatment to the metal lines and the insulating layer having the void.

2. The method of claim 1, comprising polishing the insulating layer to expose the metal lines.

3. The method of claim 2, comprising:
forming photodiodes over the semiconductor substrate;
forming an interlayer insulating film over the photodiodes;
forming color filter layers over the interlayer insulating film; and
forming micro lenses over the color filter layers,
wherein a guard line of a chip is formed after the micro lenses are formed.

4. The method of claim 2, comprising forming a flash memory device.

5. The method of claim 1, wherein the metal lines and the insulating layer form a guard line of a chip including the lower structure.

6. The method of claim 1, wherein the metal lines are formed by a photolithography process using an etching mask layer.

7. The method of claim 6, wherein forming the void is controlled by adjusting a width of an open area of the etching mask layer.

8. The method of claim 6, wherein a distance between the metal lines with the void formed therebetween is substantially equal to a width of an open area of the etching mask layer.

9. The method of claim 6, wherein the metal lines are formed adjacent to one another, and wherein a distance between the adjacent metal lines is approximately 0.09 μm to 0.15 μm.

10. The method of claim 1, wherein the insulating layer comprises an inter-metal dielectric film.

11. The method of claim 1, wherein the metal lines comprise aluminum (Al).

12. A device, comprising:
adjacent metal lines formed over a lower structure formed over a semiconductor substrate; and
an insulating layer formed between the adjacent metal lines and having a void between the adjacent metal lines.

13. The device of claim 12, wherein the adjacent metal lines and the insulating layer having the void undergo heat treatment.

14. The device of claim 12, wherein the adjacent metal lines and the insulating layer correspond to a guard line of a chip including the lower structure.

15. The device of claim 12, comprising:
photodiodes over the semiconductor substrate;
an interlayer insulating film over the photodiodes;
color filter layers over the interlayer insulating film; and
micro lenses over the color filter layers.

16. The device of claim 12, comprising a flash memory device.

17. The device of claim 12, wherein a distance between the adjacent metal lines with the void formed therebetween is approximately 0.09 μm to 0.15 μm.

18. The device of claim 17, wherein a width of each adjacent metal line is approximately 0.16 μm.

19. The device of claim 12, wherein the insulating layer comprises an inter-metal dielectric film.

20. The device of claim 12, wherein the metal lines comprise aluminum (Al).
